(19) United States
(12) Patent Application Publication
(10) Pub. No.: US 2017/0279351 A1
(43) Pub. Date: Sep. 28, 2017

(54) STABILIZED NON-INDUCTIVE VOLTAGE BOOST CONVERTER OPERATING AT MOS SUB-THRESHOLD VOLTAGE FROM ANALAGOUS MICROPOWER PYROELECTRIC DEVICE

(71) Applicant: BOARD OF REGENTS OF THE UNIVERSITY OF TEXAS SYSTEM, Austin, TX (US)

(72) Inventors: Shuza BINZAID, San Antonio, TX (US); Amar S. BHALLA, Helotes, TX (US); Ryan GUO, Helotes, TX (US); MD Qumrul HASAN, Las Cruces, NM (US)

(21) Appl. No.: 15/506,738

(22) PCT Filed: Aug. 26, 2015
(86) PCT No.: PCT/US2015/047061

§ 371 Date: Feb. 26, 2017

Related U.S. Application Data
(60) Provisional application No. 62/042,197, filed on Aug. 26, 2014.

(51) Int. Cl. H02M 3/08; H02N 10/00; H02M 3/06; H02M 3/18; H01L 37/02; H03F 3/42

(52) U.S. Cl. CPC H02M 3/08; H01L 37/02; H03F 3/423; H02M 3/06; H02M 3/18; H02N 10/00

(57) ABSTRACT

Disclosed herein is a non-Inductive voltage boost-converter (NVBC) for micro-power energy harvesting systems for energy storage and delivery applications. Current devices deliver a wide-range of micro-power having only up to 0.8V peak-voltage, but nominally 0.45V in lab test conditions. This voltage is not adequate in charging storage cells such as rechargeable batteries and also driving electronic circuits. Technology is in demand where a boost-converter must operate at MOS sub-threshold voltage (Sub-V_{TH}) limits. Disclosed herein is a novel NVBC device that has eliminated the need of an inductor coil and associated high-speed switching circuits; thus achieving higher efficiency. The disclosed invention applies a simple self-synchronizing technique to adapt the NVBC automatically to the low-frequency energy signal of a pyroelectric device. A novel NVBC is presented for stabilized output of NVBC (S-NVBC). In an embodiment, the S-NVBC achieves an efficiency of 86%.

### CROSS-REFERENCE TO RELATED APPLICATIONS

This application claims priority to, and is the National Stage of International Application No. PCT/US15/47061 filed on Aug. 26, 2015 and claims priority of U.S. Provisional Patent Application Ser. No. 62/042,197, filed on Aug. 26, 2014, the contents of which are incorporated by reference in their entirety.

### STATEMENT REGARDING FEDERALLY SPONSORED RESEARCH OR DEVELOPMENT

Not applicable

### FIELD OF THE INVENTION

The present invention generally relates to a device, system, and method for voltage boosting.

### BACKGROUND OF THE INVENTION

Pyroelectricity is a state of electrical polarization produced (as in a crystal) by a change in temperature. Pyroelectricity, is the development of opposite electrical charges on different parts of a crystal that is subjected to temperature change. When pyromaterials are heated or cooled they generate a temporary voltage known as pyroelectricity. Spontaneous polarization is temperature dependent, so a change in temperature which induces a flow of charge to and from the surfaces. This is the pyroelectric effect. All polar crystals are pyroelectric, so the 10 polar crystal classes are sometimes referred to as the pyroelectric classes. The property of pyroelectric crystal is to measure change in net polarization (a vector) proportional to a change in temperature. If a crystal develops a positive charge on one face during heating, it will develop a negative charge there during cooling. The charges gradually dissipate if the crystal is kept at a constant temperature. The total pyroelectric coefficient measured at constant stress is the sum of the pyroelectric coefficients at constant strain (primary pyroelectric effect) and the piezoelectric contribution from thermal expansion (secondary pyroelectric effect). Pyroelectric materials can be used as infrared and millimeter wavelength detectors.

Various types of pyroelectric devices deliver a wide-range of micro-power having only up to 0.8V peak-voltage, but nominally 0.45V in lab test condition. Pyroelectric materials generally produce 0.3˜0.8V. Unfortunately, 0.8V is not sufficient to run an electronic device that runs by a single battery. This pyroelectric voltage needs to be boosted to at least 1.45V. Presented herein is a boost converter that can boost a pyroelectric voltage from 0.4V to 1.5V.

In an embodiment, an inductive voltage boost converter is presented. A pyroelectric emulator is used (previously designed at MeMDRL) as a pyroelectric device voltage source. In the inductive voltage boost converter a MOSFET transistor for switching and a diode for forwarding biasing purpose is utilized. Configured in the device is a variable frequency clock pulse generator to operate transistor efficiently. In this clock pulse generator, a potentiometer for generating variable clock pulses is utilized.

In this embodiment, the capacitor, directional charging current path, and transistor produced much larger degradation effect at output. The transistor produces a leakage current path between each gate and drain due to switching delay for clock speed. The directional charging current path has also drawn small leakage current in its reverse mode. When the transistor is in off-mode, capacitor discharge through directional charging device creates transistor leakage current path. Non-zero crossing low-power signal of pyroelectric device is experienced. In this embodiment, inductive voltage boost converter experiences some leakage current and loss of signal driving power, ripple voltage and so on. Thus, the efficiency of the inductive voltage boost converter cannot be very high. The leakage region based on time where the diode and the MOSFET create a leakage path.

The initial embodiment of the inductive voltage boost converter presents some issues of leakage current, ripple voltage and so on. Therefore a further embodiment is also presented and characterized as a non-inductive micro-power voltage boost converter. In this configuration only capacitors for charge storing purposes are utilized, thus creating stacked voltage through the directional current devices.

### BRIEF SUMMARY OF THE INVENTION

Disclosed herein is a “Stabilized Non-Inductive Voltage Boost Converter” (S-NVBC) circuit. The device is able to boost pyroelectricity from 0.3˜0.4V to 1.45V to run electronic devices. In some aspects the NVBC has eliminated the need of an inductor coil and associated high-speed switching circuits; thus achieving higher efficiency. In some aspects, the invention applies a simple self-synchronizing technique that adapts the NVBC automatically to the low-frequency energy signal of pyroelectric devices. In some aspects, the invention uses only capacitors for charge storing purposes, thus creating stacked voltage through the directional current devices.

In some embodiments the invention is a circuit comprising 4CN₀+(4P+4C)N_{l,m-1}+4PNₘ+miR+mjC+mk(R+C) wherein, C is the charge collector, P is the directional current paths, R is rail resistance, N is the stage (a letter) and m is the stage position number Also i, j and k are types of the system (Type-A, Type-B and Type-C, respectively) value is 1 if true.

In some embodiments the invention produces stabilized direct current output by mitigating any pyroelectric alternating current signal abnormality. In some aspects, each stage of voltage step-up is established by a directional quad-current path. In other aspects, the in-line charge is balanced by R, C, or RC at the nodes of power rails. In yet other aspects, ripple-free operation is assured at any pyroelectric device frequency.

In some aspects dual rails of storage components provide improved current density. In yet other aspects, step-up voltage is cascaded by the dual rail system.

### BRIEF DESCRIPTION OF THE SEVERAL VIEWS OF THE DRAWINGS

For a more complete understanding of the features and advantages of the present invention, reference is now made to the detailed description of the invention along with the accompanying figures in which:

FIG. 1 is a semiconductor design layout of a simple single stage NVBC in accordance with embodiments of the disclosure;

FIG. 2 is a block diagram of voltage boosting cascaded NVBC for 7 stages in accordance with embodiments of the disclosure;

FIG. 3 illustrates voltage boosting occurred at each cascaded NVBC stages in accordance with embodiments of the disclosure;

FIG. 4 illustrates capacitor charging and discharging in accordance with embodiments of the disclosure;

FIG. 5 is a schematic diagram of S-NVBC Type A—Capacitive module in accordance with embodiments of the disclosure;

FIG. 6 is a simulation result of Type-A S-NVBC no-load condition in accordance with embodiments of the disclosure;

FIG. 7 is a simulation result of Type-A S-NVBC with load condition in accordance with embodiments of the disclosure;

FIG. 8 illustrates voltage and current relationship in accordance with embodiments of the disclosure;

FIG. 9 is a schematic diagram of S-NVBC Type B Resistive in accordance with embodiments of the disclosure;

FIG. 10 is a simulation result of Type-B S-NVBC with no load condition in accordance with embodiments of the disclosure;

FIG. 11 is a simulation result of Type-B NVBC with load condition in accordance with embodiments of the disclosure

FIG. 12 illustrates RC voltage relationship in accordance with embodiments of the disclosure;

FIG. 13 is a schematic diagram of S-NVBC Type C frequency in accordance with embodiments of the disclosure;

FIG. 14 is a simulation result of Type-C S-NVBC with no load condition in accordance with embodiments of the disclosure;

FIG. 15 is a simulation result of Type-C S-NVBC with load condition in accordance with embodiments of the disclosure;

FIG. 16 is a single stage S-NBVC module in accordance with embodiments of the disclosure;

FIG. 17 is a single stage Non Inductive Voltage Boost Converter module in accordance with embodiments of the disclosure;

FIG. 18 illustrates a Diode BAT46 test in accordance with embodiments of the disclosure;

FIG. 19 illustrates an output DC voltage waveform of S-NVBC in accordance with embodiments of the disclosure;

FIG. 20 illustrates an input pyroelectric AC like voltage waveform in accordance with embodiments of the disclosure;

FIG. 21 illustrates using S-NVBC from micropower pyroelectric voltage, the wrist watch is running without any battery in accordance with embodiments of the disclosure;

FIG. 22 is for input voltage 0.116V in accordance with embodiments of the disclosure;

FIG. 23 is for input 0.15V in accordance with embodiments of the disclosure;

FIG. 24 is for input voltage 0.3V in accordance with embodiments of the disclosure; and

FIG. 25 is for input voltage 0.353V in accordance with embodiments of the disclosure.

### DETAILED DESCRIPTION OF THE INVENTION

Developed and described herein is a novel Stabilized Non-Inductive Voltage Boost Converter (S-NVBC).

### Non-Inductive Voltage Boost Converter

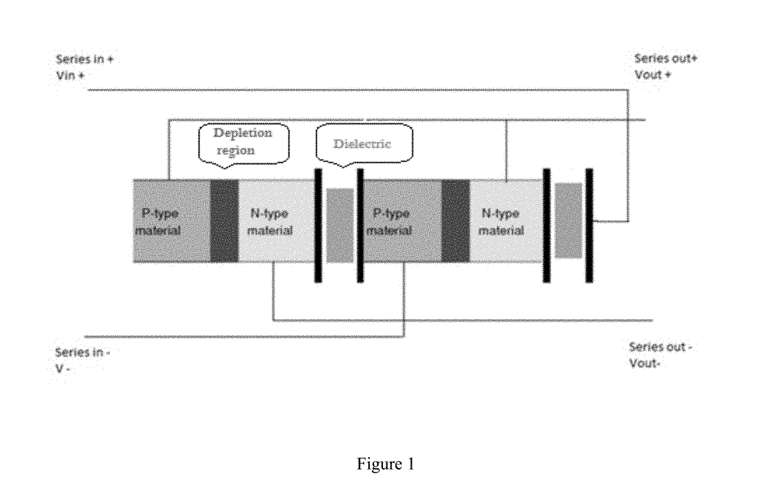

A semiconductor design configuration for a non-inductive voltage boost converter is shown in FIG. 1. It is the simplest form of the design of a single stage circuit, but it is not very stable as a non inductive voltage boost converter (NVBC). Still, this circuit has advantages:
1. Provides a capacitive solution for a boost converter.
2. Booster current losses are minimized by charging the in line capacitors.
3. Power loss is minimized by eliminating current loss and increasing voltage in the capacitors.

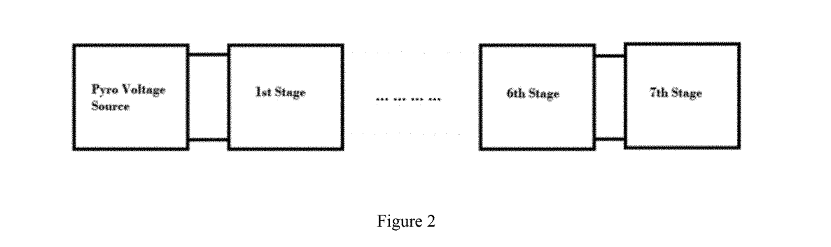

In FIG. 2 the seven stage semiconductor design view of chip components of a simple NVBC is shown. However, a cascaded 7 stage voltage boost converter has been used. Each single stage boost conversion is equivalent to FIG. 1.
1. This circuit is comprised of capacitors and directional current devices.
2. While this configuration has the benefits of simplicity by using less components, its output has very poor ripple characteristics.
3. The ripple voltage can be controlled under load condition and negligible under no load conditions.

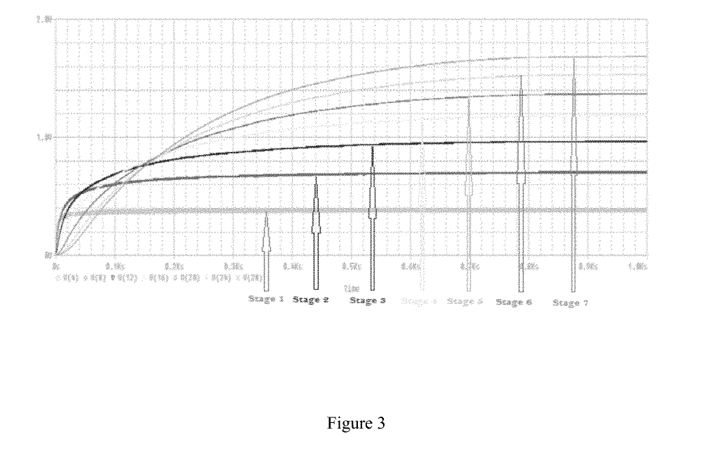

FIG. 3 shows voltage boosting occurred at each cascaded NVBC stage. In this figure we can clearly see that at the 1st stage S-NVBC boosts 1× and 2nd stage 2×. It added 1× at each cascaded stage. The desired target values were achieved with 1.45V at the 6th stage and also 1.67V at the 7^{th} stage.

### Stabilized Non-Inductive Voltage Boost Converter

In an embodiment a stabilized DC voltage from a non-inductive voltage boost converter has the following features:
1. Step-up micro power pyro-voltage to higher output voltage.
2. Boost 0.4V to 1.45V for an electronic device that normally runs with a battery.
3. Minimize any additional current losses.
4. Eliminate ripple voltage effects.
5. Increase efficiency beyond inductive boost converter design (greater than 80%)

In an embodiment, the stabilized non-inductive voltage boost converter circuit utilizes a pyroelectric emulator as a pyroelectric voltage device to source the micro power. A material is considered to exhibit the pyroelectric effect when a change in the material's temperature with respect to time (temporal fluctuation) resulting in the production of electric charge.

An S-NVBC is an electrical circuit that converts pyroelectricity from a low voltage to a high DC voltage, typically using a network of capacitors that has directional charging current path. Three embodiments of the S-NVBC are presented herein, based on components used between rails of ground and output:
1. Type A—Capacitive
2. Type B—Resistive
3. Type C—RC (frequency)

Type A—Capacitive: The Type-A has capacitors connecting nodes of the rails in the design. A capacitor is a non-linear device. A capacitor is a passive electric device that stores electric charges. A common capacitor is made of two parallel conductive surfaces of area A each, separated by an insulation layer of thickness d, and it has a capacitance of:

$$C = {ɛ}_{0} k \frac{A}{d}$$

Where C is the capacitance in farads, A the area of each plate in m2, d the insulation (dielectric) thickness in (m), and εo the permittivity of free space (vacuum) for electric field propagation expressed in F/m. The factor κ, pronounced as “kappa” denotes the dielectric constant, and it depends on the material of the insulation layer. The capacitance C does not depend on the material of the conductive plates.

Capacitor stores charges, and create voltage potential, V across conductive surfaces that is proportional to the charge stored, given by the relationship V=q/C, where C is called the capacitance.

$$I ( t ) = C \frac{dV ( t )}{dt}$$

So capacitor voltage cannot change instantaneously. However, capacitor current becomes very high at t=0.

At the transient state, Capacitor voltage begins at zero and exponentially increases to V volts. Capacitor current instantaneously jumps to infinity and exponentially decays to zero.

$$V ( t ) = {V}_{0} ( 1 - {e}^{- \frac{t}{RC}} )$$

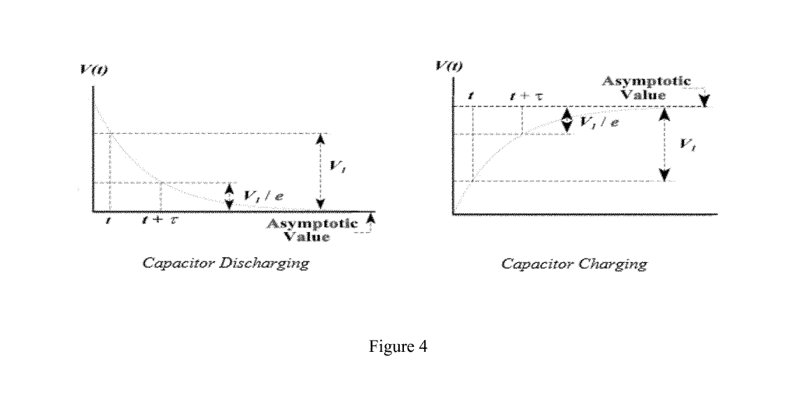

At the beginning of discharging state, Capacitor C voltage has V volts across it when it begins to discharge. Capacitor current will instantly jump to −I. Both voltage and current will decay exponentially to zero shows in FIG. 4.

$${V}_{C} = \frac{{Q}_{0}}{C} {e}^{\frac{- t}{τ}}$$

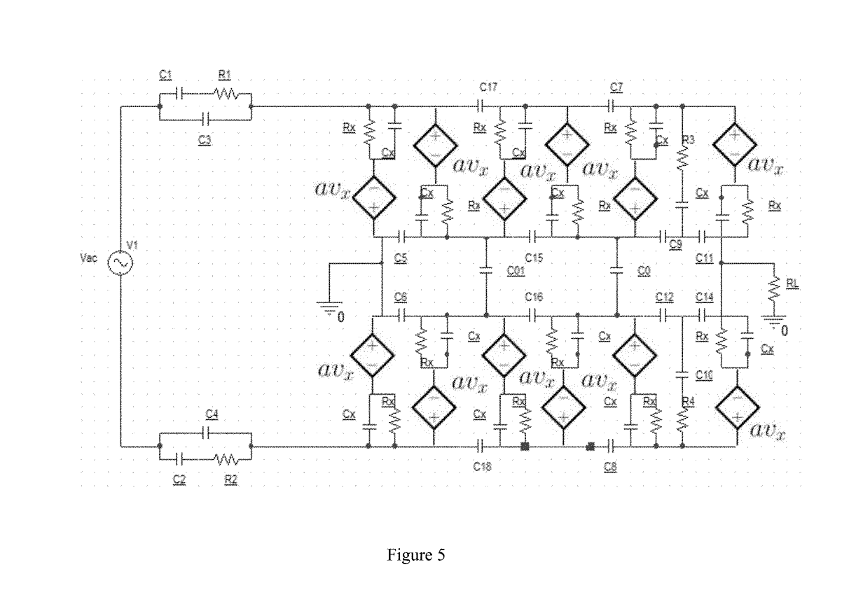

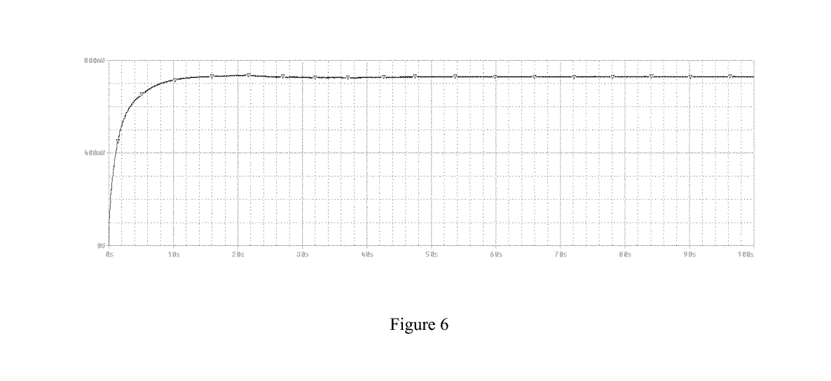

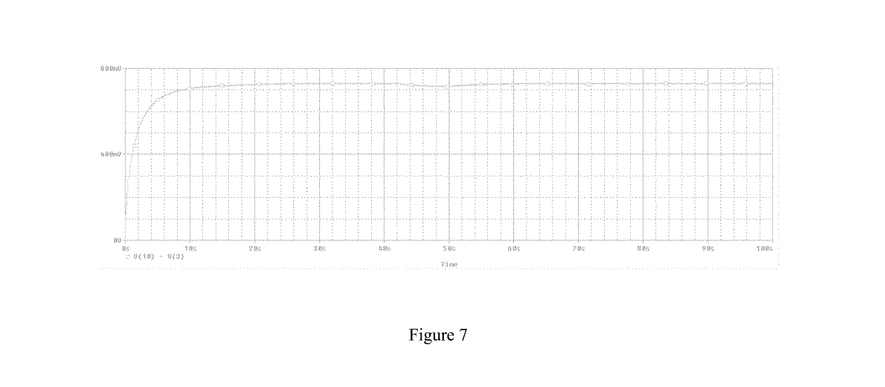

In FIG. 5, a schematic diagram of the S-NVBC Type A—Capacitive module is presented. In FIGS. 6 and 7, simulation results of the Type-A S-NVBC with no load condition and load condition is shown. Comparing these results, in load condition there is more ripple experienced than in a no load condition.

Type B—Resistive: The type B has resistors connecting nodes of the rails in the design. Resistance can be linear. Linear resistance obeys Ohm's Law and controls or limits the amount of current flowing within a circuit in proportion to the voltage supply connected to it and therefore the transfer of power to the load.

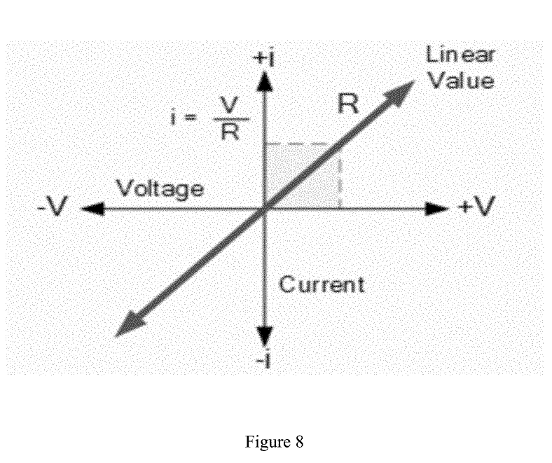

The relationship between Voltage, Current and Resistance forms the basis of Ohm's law which in a linear circuit states that if we increase the voltage, the current goes up and if we increase the resistance, the current goes down. Then we can see that current flow around a circuit is directly proportional (∝) to voltage, but inversely proportional (1/∝) to resistance (FIG. 8).

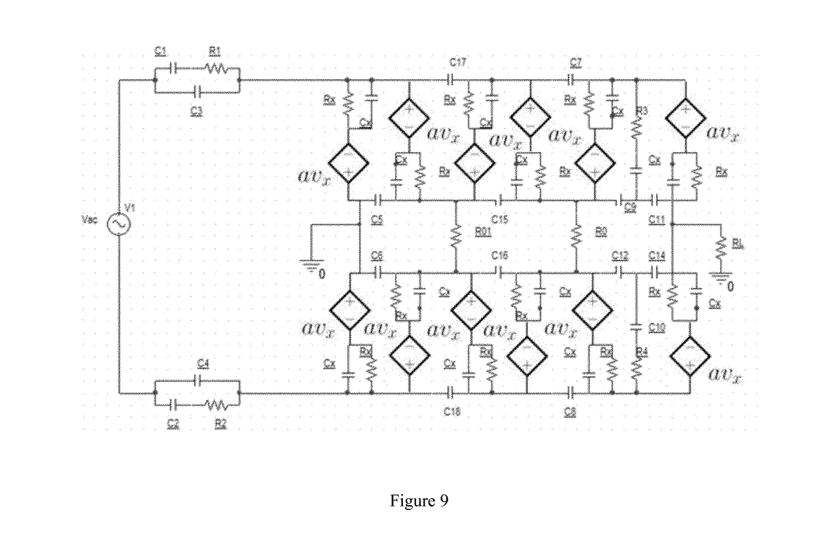

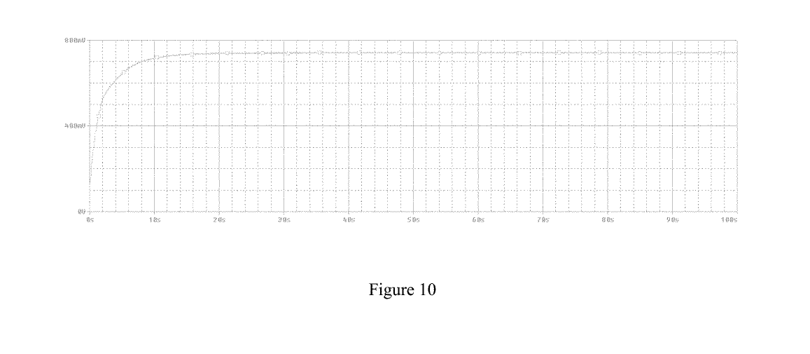

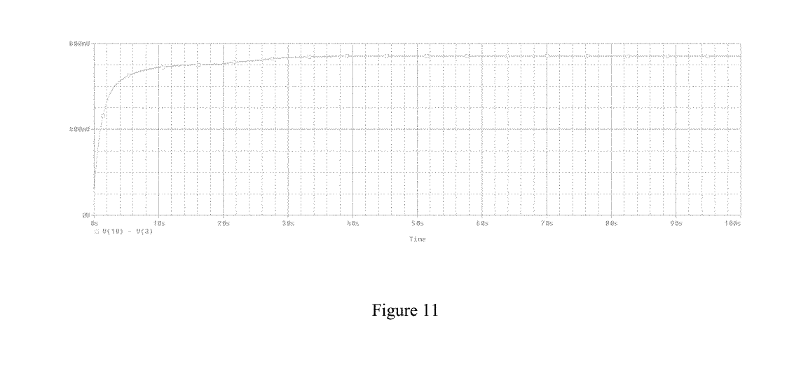

In FIG. 9 a schematic diagram of a S-NVBC Type B—Resistive module is presented. In FIGS. 10 and 11, simulation results of the Type—B S-NVBC with no load condition and load condition is shown. Comparing these results, in load condition there is more ripple experienced than in a no load condition.

Type C—Frequency: The type C has capacitors and resistors connecting nodes of the rails in the design. RC circuit is composed of resistor and capacitor. RC circuits can be used to filter a signal by blocking certain frequencies that can cause unbalanced load performance.

The capacitor discharges its stored energy through the resistor. The voltage across the capacitor is RC time dependent, can be expressed by Kirchhoff's current law, where the current through the capacitor must equal the current through the resistor. This results in the linear differential equation

$$\frac{1}{R} V + C \frac{dV}{dt} = 0$$

Solving this equation for V yields the formula for exponential decay:

$$V ( t ) = {V}_{0} {e}^{- \frac{t}{RC}}$$

Where V0 is the capacitor voltage at time t=0.

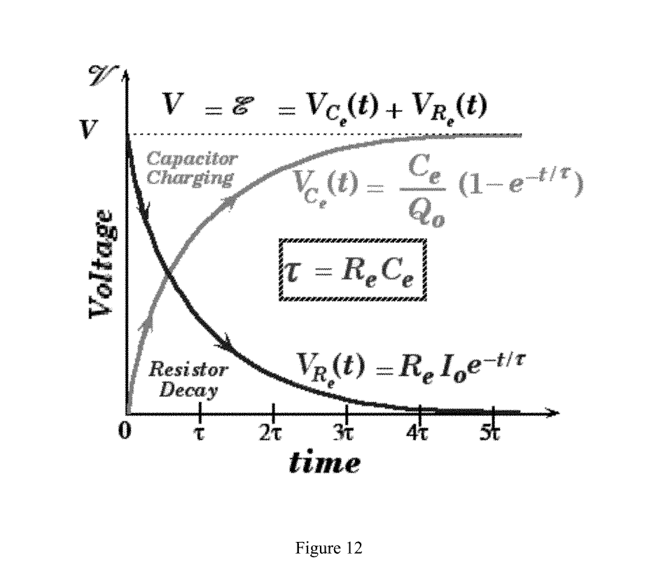

RC time constant is shown in FIG. 12

When pyroelectric AC source is applied to the parallel RC circuit shown below the capacitor never reaches a final charge and therefore it will always carry some current. We know that the voltage in a parallel circuit must be the same throughout the circuit. However, the current through R is not the same as the current through C. Thus, I_{R} is in phase with V, but I_{C} leads V by 90°.

I=I_{c}+I_{R}

We know that

$$V = {V}_{c} = {V}_{R}$$

$${I}_{R} = \frac{1}{R} V$$

$${i}_{C} = C \frac{dV}{dt}$$

$$\frac{1}{R} V + C \frac{dV}{dt} = I$$

$$\frac{dV}{dt} + \frac{1}{RC} V = \frac{1}{C} I$$

$$\frac{dV}{dt} + \frac{1}{{τ}_{RC}} V = \frac{1}{C} I$$

Total current divides at the junction into the two branch current, I_{R} and I_{C}. Total current (I) is the phasor sum of the two branch currents. Since I_{R} and I_{C} are 90° out of phase with each other, they must be added as phasor quantities.

$$I = \sqrt{{I}_{R}^{2} + {I}_{C}^{2}}$$

$$θ = {tan}^{- 1} ( \frac{{I}_{C}}{{I}_{R}} )$$

RC parallel circuit can be used as integrator, differentiator, RC filter calculator, voltage dividing circuit, Coupling and wave shaping circuits. So Type C—Frequency, RC circuit is suitable for overload condition because it has both exponential (for capacitive) and linear (for resistive) condition.

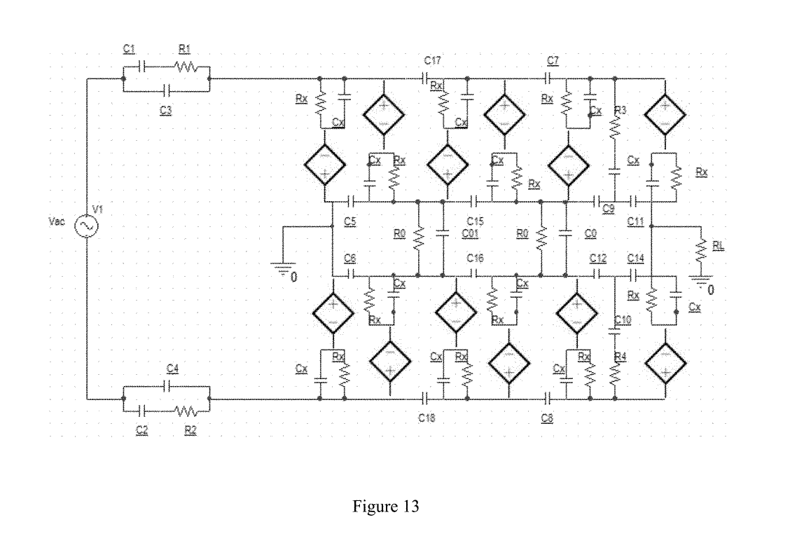

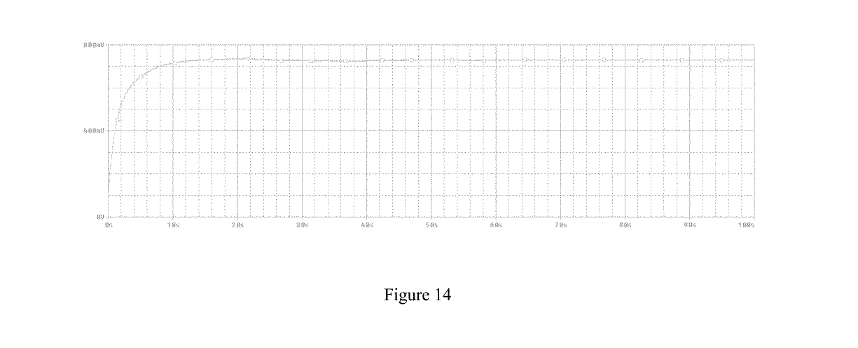

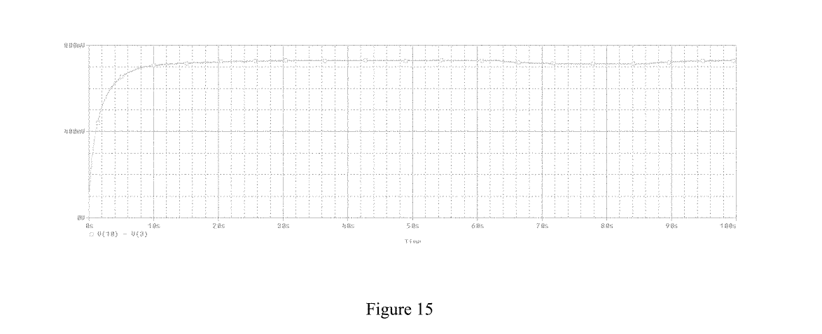

In FIG. 13 we can see a schematic diagram of S-NVBC Type C—frequency module. In FIGS. 14 and 15 we show simulation results of Type-C S-NVBC with no load condition and load condition. Comparing these results we can conclude that in load condition we get more ripple than no load condition.

In the normal loaded condition Type A—capacitive S-NVBC is more stabilized in higher frequencies than type B (resistive). Type B is more suitable for smaller load condition than Type A. In addition, in the overloaded condition Type C—(Frequency) S-NVBC is more stabilized than type B (resistive) and type A (Capacitive).

### Hardware Design of Stabilized Non-Inductive Voltage Boost-Converter (S-NVBC).

The PSPICE simulated circuit that was modeled for S-NVBC is not the same as the hardware setup module. In the simulation, results showed by its precise calculation using the fixed given parameters. However, in hardware, many real-time variations occurred, such as small leakage current, wire length, type and contact resistivity, component parameters etc. So, it was expected that PSPICE simulation result and real-time hardware results will not be exactly the same.

### Simple Test Setup of Stabilized Non-Inductive Voltage Boost-Converter (S-NVBC)

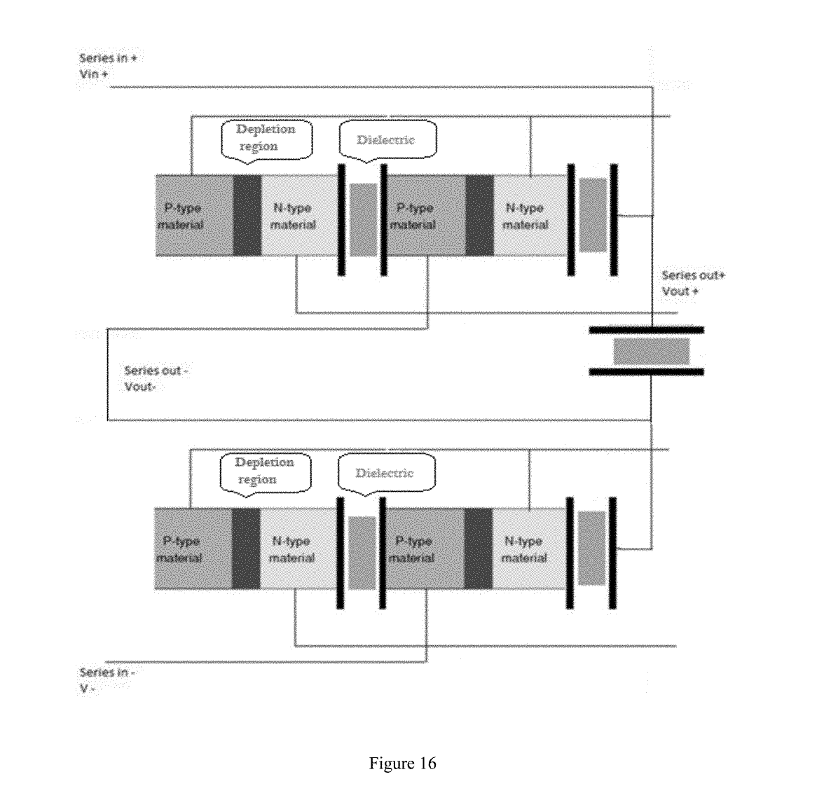

The simplest form of a single stage S-NVBC is shown in FIG. 16 for a semiconductor layout.

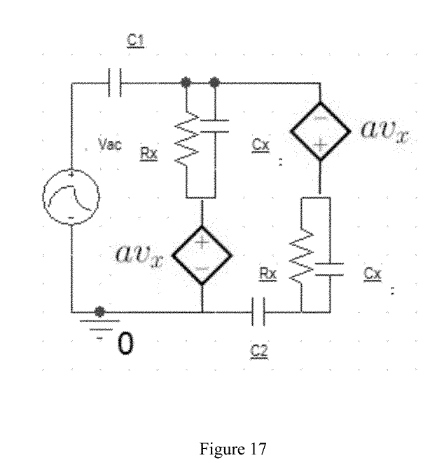

Assuming that the peak voltage of the pyroelectric AC source is +Vₛ, and that the capacitor values are sufficiently high to allow, when charged, that a current flows with no significant change in voltage shown in FIG. 17, then the (simplified) working of the cascade is as follows:
1. Negative peak (−Vₛ): The C₁ capacitor is charged through directional charging current path to Vₛ
2. Positive peak (+Vₛ): the potential of C₁ adds with that of the source, thus charging C₂ to 2Vₛ through aVx

Circuit analysis of the single stage S-NVBC will now be discussed. First, analysis on the single stage module of the circuit is described. This circuit is comprised of a capacitor that has directional current path so we have to analyze the capacitor first. We know from the capacitor equation:

$$i = c \frac{{dV}_{c}}{dt}$$

$$C {dV}_{c} = idt$$

$${dV}_{c} = \frac{1}{C} idt$$

$${\int }_{0}^{V} dV = \frac{1}{C} i {\int }_{0}^{t} dt$$

$${V}_{c} = \frac{1}{C} i {\int }_{0}^{t} dt$$

Now we have to find out the junction voltage drop. From the I-V characteristic of an ideal junction in either forward or reverse bias we get

$${I}_{D} = {I}_{s} ( {e}^{\frac{{qV}_{D}}{KT}} - 1 )$$

$${V}_{D} = \frac{KT}{q} ln \frac{{I}_{D}}{{I}_{s}}$$

Now, we know that V_{dc}_{ᵣₘₛ}=\sqrt{2}V_{dc}

$${V}_{{dc}_{rms}} = \frac{{V}_{ac}}{\sqrt{2}}$$

$${V}_{ac} = 1.41 {V}_{{dc}_{rms}}$$

For the forward voltage condition V_{ac}⁺=V_{c1}
For the reverse voltage condition V_{ac}⁻=V_{c1}−V_{D}−iR_{D}
R_{D} is small, thus it is negligible V_{o t}=V_{C2}=2V_{c}−V_{D}

Vₒᵤₜ=V_{C2}=2V_{c}−V_{TH}

Performance.

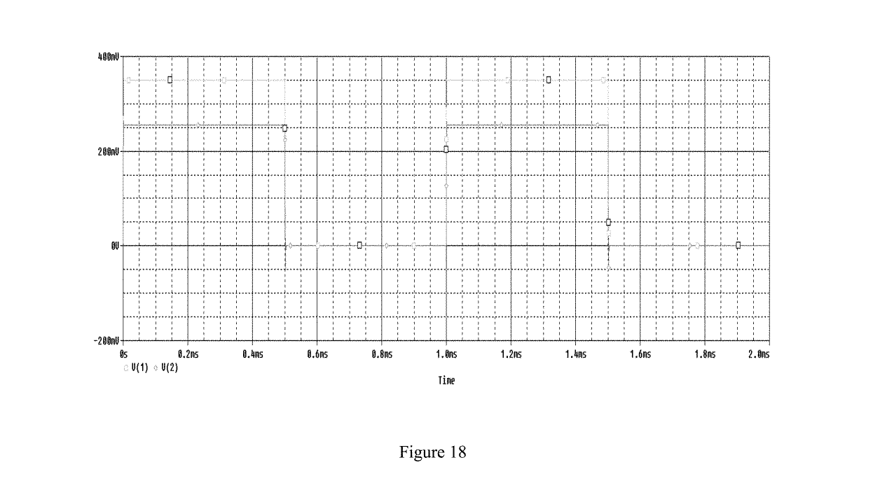

At first experimental stage we used Bat46 diode for our experiment because it is zero threshold voltage. In the Bat46 diode booster circuit our main problem was leakage current and reverse breakdown voltage as shown in FIG. 18. We found from the BAT46 diode specification that at 1.5V its maximum leakage current is 0.5 uA. At high voltage booster stages created high reverse current and damaged the output DC voltage circuit. Therefore when we tried to boost the voltage more than 1.5V BAT46 diode created reverse current and that damaged the diodes because BAT46 diodes are more sensitive. Then it produces 1× voltage at every stage output.

Proving that all diodes did not function properly at micro-power pyroelectricity, BAT46 was abandoned. The chosen one was BAT54S IC of stacked diodes, because its maximum repetitive reverse voltage is 30V. At 10 uA reverse current its breakdown voltage is 30V. Also at 25V of reverse voltage, its maximum reverse leakage current is 2 uA. From the specification, we can conclude that BAT54S is better than BAT46 for S-NVBC. BAT54S is 3 pin junction and we used it as a dual cascaded current path that also reduce circuit's space in hardware. Moreover, it has low turn-on voltage and faster switching.

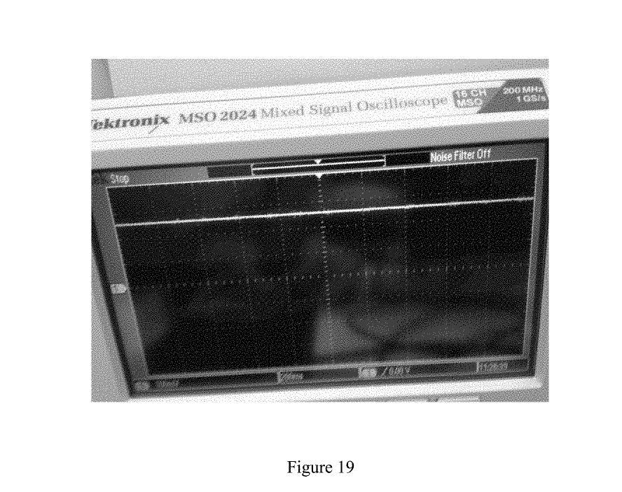

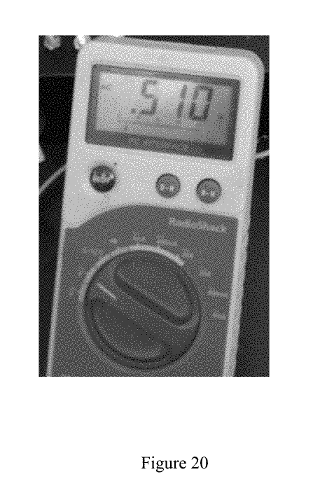

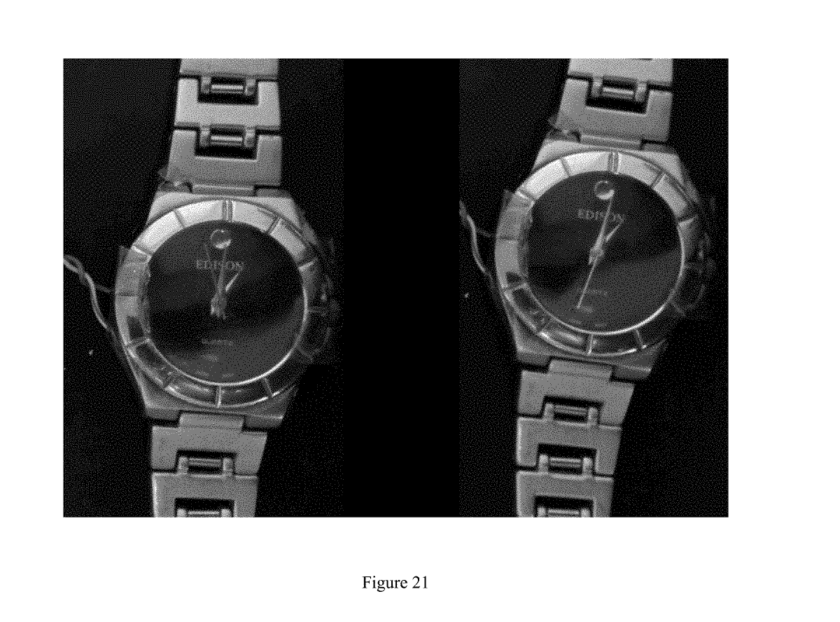

We implemented S-NVBC in hardware. Our pyroelectric input voltage was 0.3˜0.4V and we got our output voltage 1.45V, easily. So from the output voltage from S-NVBC circuit, we can run wrist watch and micro-power devices etc. The capacity of a battery is strongly dependent on the load. An effective capacity of 150 mAh at low drain, but at a load of 1 ampere, the capacity could be as little as 30 mAh. FIGS. 19 and 20 shows output and input waveform of S-NVBC respectively. FIG. 21 shows using S-NVBC from micro-power pyroelectric voltage, the wrist watch is running without any battery.

### Data, Plots, and Examples

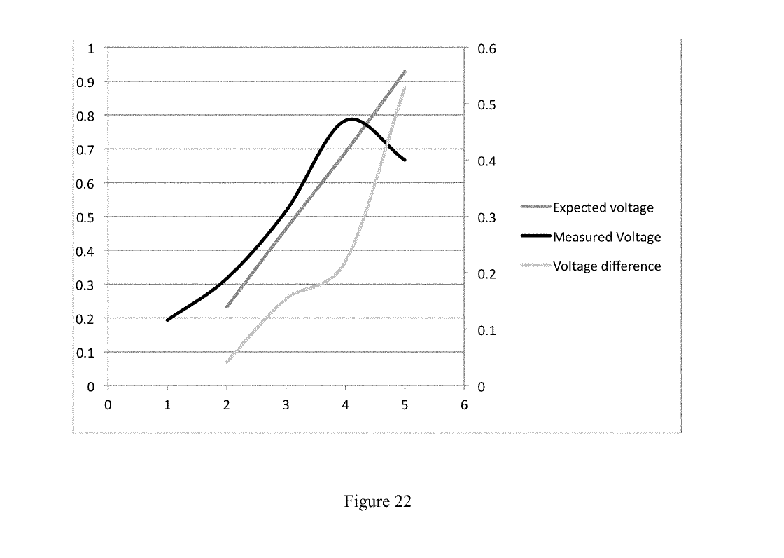

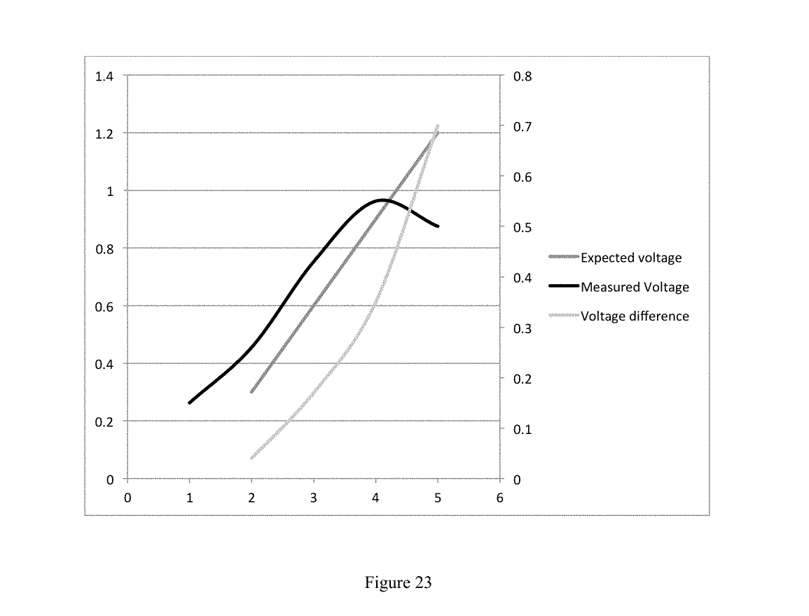

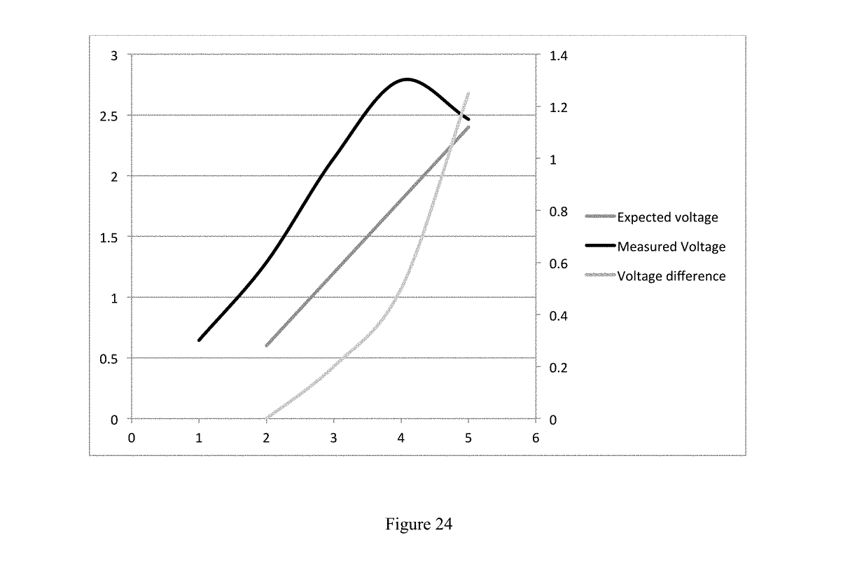

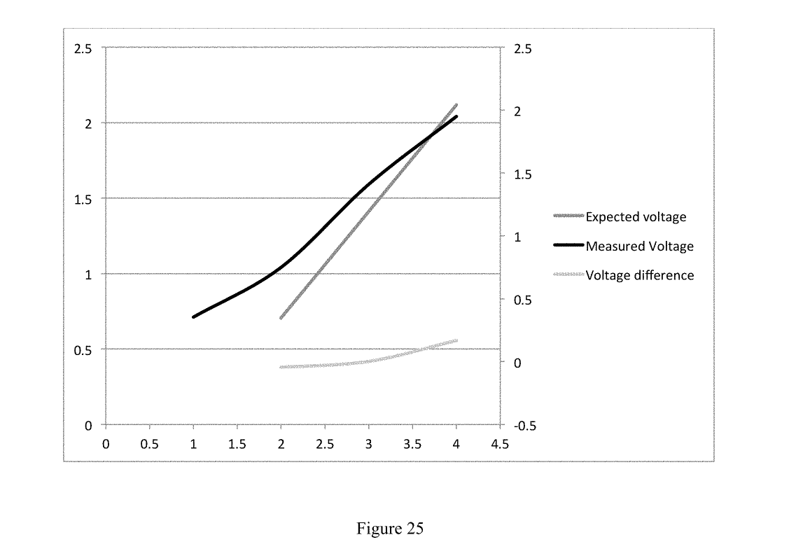

Data was collected for working condition of the S-NVBC setup. Table 1, 2, 3 and 4 presents the data of the test and FIGS. 22, 23, 24 and 25 shows plot diagram of different inputs.

TABLE 1
Cascaded setup for input voltage 0.116 V

| Cascaded | Expected | Measured | Voltage |
|---|---|---|---|
| Setup | Voltage | Voltage | Difference |
| AC Input | N/A | 0.116 | N/A |
| 2X O/P | 0.232 | 0.19 | 0.042 |
| 4X O/P | 0.464 | 0.31 | 0.154 |
| 6X O/P | 0.69 | 0.47 | 0.22 |
| 8X O/P | 0.928 | 0.4 | 0.528 |

TABLE 2
Cascaded setup for input voltage 0.15 V

| Cascaded | Expected | Measured | Voltage |
|---|---|---|---|
| Setup | Voltage | Voltage | Difference |
| AC Input | | 0.15 | |
| 2X O/P | 0.3 | 0.26 | 0.04 |
| 4X O/P | 0.6 | 0.43 | 0.17 |
| 6X O/P | 0.9 | 0.55 | 0.35 |
| 8X O/P | 1.2 | 0.5 | 0.7 |

TABLE 3
Cascaded setup for input voltage 0.3 V

| Cascaded | Expected | Measured | Voltage |
|---|---|---|---|
| Setup | Voltage | Voltage | Difference |
| AC Input | | 0.3 | |
| 2X O/P | 0.6 | 0.6 | 0 |
| 4X O/P | 1.2 | 1 | 0.2 |
| 6X O/P | 1.8 | 1.3 | 0.5 |
| 8X O/P | 2.4 | 1.15 | 1.25 |

TABLE 4
Cascaded setup for input voltage 0.353 V

| Cascaded | Expected | Measured | Voltage |
|---|---|---|---|
| Setup | Voltage | Voltage | Difference |
| AC Input | | 0.353 | |
| 2X O/P | 0.706 | 0.75 | −0.044 |
| 4X O/P | 1.412 | 1.41 | 0.002 |
| 6X O/P | 2.118 | 1.95 | 0.168 |

The minimum operating voltage=0.115V(AC) was measured. Further experiments confirmed that the rated minimum boosted voltage under load=0.28V(AC). This rated voltage produced a clean output voltage was 28 mVDC (at 2×) and also 54 mVDC (at 8×). From the above tables and graphs we can clearly see that maximum output voltage is at 6× stage, but not at 8× output voltage as it is reduced. So we decided to have max output voltage at 6× stage. Also from the Table 4 we can see that measured voltage and expected voltages are almost identical and as a result we can see the voltage difference is almost zero. We used two types of batteries A76 and CR626 for charging experiments.

### EXAMPLE #1

A76 battery: A76 battery is an alkaline 1.5 volt button cell battery. It is a round cell 11.4±0.2 mm diameter and 5.2±0.2 mm height as defined by the IEC standard 60086. It's typical capacity is 150 mAh and nominal voltage is 1.5V.

TABLE 5
Charging status of A76 battery

| Battery Charging | Battery Type: A76 | Time |
|---|---|---|
| Input V = 0.62 V(ac) | Vbat(sat) = 1.22 V | 3.15 pm |
| Input I = 5.7 uA(ac) | Vbat(end) = 1.44 V | 12.15 pm |
| Input P = | Voltage | Total |
| 3.534 uW~3534 nW | Difference = 0.22 V | time 21 hr |

Summary of Parameters: A76 Battery
Voltage=1.47V Discharge current=500 mA
Vpyro=0.62V(ac) at 4.75 Hz, Ipyro=5.7 uA
Vboost(open)=1.9V
Vboost(load)=1.6V

Results:
Vbat(discharge)=1.22V started at 3:15 pm 8/20/13
Vbat(end)=1.44V saturated at 12:15 pm 8/21/13
Total charging time 21 hrs; Delta-Voltage=0.22V

### EXAMPLE #2

CR626 battery: CR626 battery is a button cell battery. Coin-shaped cells are thin compared to their diameter. The metal can is the positive terminal, and the cap is the negative terminal. The IEC prefix “CR” denotes lithium manganese dioxide chemistry. Its typical capacity is 30˜160 mAh and nominal voltage is 1.5V. Its standard discharge current is 0.1˜0.2 mA.

TABLE 6
Charging status of CR626 battery

| Battery Charging | Battery Type: CR626 | Time |
|---|---|---|
| Input V = 0.62 V(ac) | Vbat(sat) = 1.206 V | 1.05 pm |
| Input I = 5.7 uA(ac) | Vbat(end) = 1.379 V | 5.55 pm |
| Input P = | Voltage | Total |
| 3 .534 uW~3534 nW | Difference = 0.18 V | time 4.5 hr |

Summary of parameters: CR626 Battery:
Voltage=1.53V Discharge current=125 mA
Vpyro=0.62V(ac) at 4.75 Hz, Ipyro=5.7 uA
Vboost(open)=1.9V
Vboost(load)=1.6V

Results:
Vbat(discharge)=1.206V started at 1:05 pm 8/21/13
Vbat(end)=1.397V saturated at 5:50 pm 8/21/13
Total charging time 5.50 hrs; Delta-Voltage=0.18V

In order to charge a battery we have to boost the voltage at 1.3V. At Vac input=0.245V at 6× we got output Vdc=1.3V. We can see that at 8× we got output voltage lower than 6× voltages. As a result we choose 6×. After setup of the circuit we charged two batteries A76 & CR626. CR626 is one-fifth size of A76 battery.

### Discussion on Performance

The previous examples show the capabilities to run a wrist watch calculator and different types of micro-power electronic devices

No-Load Tests: the circuit used 0.08 uA at 0.695V during open-circuit test.

Full-Load Tests: the watch ran using 0.6 uA at 0.645VAC (pyro-voltage) at input by converting to 1.9VDC for the watch. It was intentionally set to higher voltage to compare with battery charging conditions. The watch consumed only 0.334 uW. Emulator was setup to a full-load test condition.

The watch normally runs at 0.42V pyroelectric voltage converted to 1.45V by the S-NVBC at full-load test condition.

The circuit showed a negligible amount of ripple at output voltage after stabilization.

Stabilized voltage boost-converter was at 86% efficiency for the full-load test.

This S-NVBC proved to be excellent for running electronic devices directly without any battery (such as small power wrist watch, calculator etc.), because it has negligible ripple voltage of DC power output.

The design of the “Stabilized Non-Inductive Voltage Boost Converter” circuit has met the requirements as expected that are described in the specifications. An objective was to boost pyroelectricity 0.3˜0.4V to 1.45V to run electronic devices. Various types of architectures and configurations have been disclosed to do model an S-NVBC circuit.

Mentioned earlier is that the first experimental stage used a Bat46 diode for configurations because it runs at zero threshold voltage. In the Bat46 diode booster circuit, concerns were leakage current and reverse breakdown voltage. At high voltage booster stages created high reverse current and damaged the output DC voltage circuit. Also utilized was the BAT54S diode because of maximum repetitive reverse voltage is 30V and it has 10 uA reverse current for its breakdown voltage. At 25V reverse voltage, its maximum reverse leakage current is 2 uA. BAT54S is a 3 pin junction type semiconductor IC and is used as cascaded directional current path that also reduces space. For analogous signal, it also has very low turn-on voltage and faster switching characteristics.

The S-NVBC has been configured in three ways—Type A Capacitive, Type B—Resistive and Type C—RC (frequency). In the normal loaded condition Type A—capacitive voltage boost converter is more stabilized than type B (resistive) for higher frequencies. In addition, in the overloaded condition Type C—(Frequency) Voltage Boost Converter is more stabilized than type B (resistive) and type A (Capacitive).

The disclosed device, system, and methods are generally described, with examples incorporated as particular embodiments of the invention and to demonstrate the practice and advantages thereof. It is understood that the examples are given by way of illustration and are not intended to limit the specification or the claims in any manner.

To facilitate the understanding of this invention, a number of terms may be defined below. Terms defined herein have meanings as commonly understood by a person of ordinary skill in the areas relevant to the present invention.

Terms such as “a”, “an”, and “the” are not intended to refer to only a singular entity, but include the general class of which a specific example may be used for illustration. The terminology herein is used to describe specific embodiments of the invention, but their usage does not delimit the disclosed device or method, except as may be outlined in the claims.

Consequently, any embodiments comprising a one component or a multi-component device or system having the structures as herein disclosed with similar function shall fall into the coverage of claims of the present invention and shall lack the novelty and inventive step criteria.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific device, system, and methods described herein. Such equivalents are considered to be within the scope of this invention and are covered by the claims.

All publications, references, patents, and patent applications mentioned in the specification are indicative of the level of those skilled in the art to which this invention pertains. All publications, references, patents, and patent applications are herein incorporated by reference to the same extent as if each individual publication, reference, patent, or patent application was specifically and individually indicated to be incorporated by reference.

In the claims, all transitional phrases such as “comprising,” “including,” “carrying,” “having,” “containing,” “involving,” and the like are to be understood to be open-ended, i.e., to mean including but not limited to. Only the transitional phrases “consisting of” and “consisting essentially of,” respectively, shall be closed or semi-closed transitional phrases.

The device, system, and methods disclosed and claimed herein can be made and executed without undue experimentation in light of the present disclosure. While the device, system, and methods of this invention have been described in terms of preferred embodiments, it will be apparent to those skilled in the art that variations may be applied to the device, system, and/or methods and in the steps or in the sequence of steps of the method described herein without departing from the concept, spirit, and scope of the invention.

More specifically, it will be apparent that certain components, which are both shape and material related, may be substituted for the components described herein while the same or similar results would be achieved. All such similar substitutes and modifications apparent to those skilled in the art are deemed to be within the spirit, scope, and concept of the invention as defined by the appended claims.

### REFERENCES

1. J. Xie, P. P. Mane & K. L. Kam, “Energy harvesting by pyroelectric effect using PZT,” Asme Conf. Smart Materials, Adaptive Intelligent Syst., vol. SMASIS 2008-605, p. 2, October 2008.
2. A. Odon, &, “Modelling and simulation of the pyroelectric detector using MATLAB/Simulink.,” Measurement Science Rev., vol. 10, no. 6, p. 3, 2010.
3. K. A. Batra & A. Bhalla, “Simulation of energy harvesting from roads via pyroelectricity,” J. Photonics for Energy, vol. 1, p. 1, 2011.
4. S. Efftoymiou & K. B. Ozanyan, “Pulsed performance of pyroelectric detectors,” J. Physics, vol. 178 012044, p. 3, 2009.
5. http://www.gdp.if.pwr.wroc.pl/pliki/pyroelectric-effect.pdf
6. http://en.wikipedia.org/wiki/Pyroelectricity
7. K. I. Hwu & Y. H. Chen, “A novel voltage boosting converter with passive voltage clamping,” Icset, 2008.
8. S. B lang, “pyroelectricity: from ancient curiosity to modern imaging tool”, Physics today, (2005).
9. B. Brewster, “observations on the pyroelectricity of minerals”, Edindsburgh. J. Sci, I (1824), 208-215.
10. M. R Srinivasan, “pyroelectric materials”, Bull mater. Sci 6 (1984) 317-325.
11. V. Danvien “Numerical and experimental study of a pyroelectric energy converter for harvesting waste heat” University of California, Los angles, 2008.
12. W. Yaw Chung, S. Tai-ping & Y. Kaw, “design of pyroelectric read-out circuitry based on Lita03 detectors.” IEEE, vol. 96, March 1996.
13. Laser components “Infra Tec”, detectors basics, pyroelectricity library.
14. W. P. Wheless, J. A. Wells &, “An equivalent-circuit radiation sensor model,” IEEE-dept Elect. Eng-university Alabama, vol. 94, March 1994.
15. Sandeep Kumar Bompthapali, “Electronic Simulator Module for Pyroelectric Devices”, MSEE project report.
16. http://faraday.physics.utoronto.ca/IYearLab/capacitor.pdf
17. http://faculty.wwu.edu/vawter/PhysicsNet/Topics/DC-Current/RCSeries.html

What is claimed is:

1. A voltage boost converter system for boosting a supply voltage, the voltage boost converter system comprising: a circuit that provides the means for a stable conversion in power from a low voltage (both zero and non-zero crossing) to a DC voltage.

2. The system in claim 1, wherein said circuit converts noisy non-sinusoidal AC (alternating current or analogous zero-crossing) voltage to a DC voltage with a noise-free peak.

3. The system in claim 1, wherein said system is further configured as a non-inductive voltage conversion at sub-threshold voltage of standard MOS.

4. The system in claim 1, wherein said system is further configured for converting a lower voltage of pyroelectric materials to a higher usable voltage for component levels of electronic applications.

5. The system in claim 1, wherein said system provides a means for reduced leakage current by taking any leakage and re-utilizing for voltage boosting purposes.

6. The system in claim 5, wherein said system is further configured for high direct-driving efficiency (>86.5%) for ultra-low driving current (5.7 uA<) boosted at 1.45VDC for end-user application.

7. The system of claim 1, wherein said system is further configured to be usable with pyroelectric emulator systems for correlation and power verification of electronic materials and devices at front-end design applications.

8. The system of claims 1, wherein said systems are further configured to be adaptable in end-user system design and applications.

9. The systems of claims 1, wherein said systems are further configured to run at a sub-micro-ampere current level at about 0.3 uA and above.

10. The systems of claims 1, wherein said systems are further configured to run devices at sub-micro-watts greater than 0.25 uW from a sub-threshold voltage.

11. The systems of claims 1, wherein said systems are further configured to convert power and act as self-charge storage to compensate and assure stabilized voltage for direct-driving electronics.

12. The systems of claims 1, wherein said systems are further configured to be very efficient as a non-inductive voltage booster circuit.

13. The systems of claims 1, wherein said systems are configured as capacitive, resistive and time-constant based applications depending on the load condition.

14. The systems of claim 1, where said system is further configured as a semiconductor design capable for embedded power conversion application.

15. The systems of claim 1, wherein said system is further configured to cascade to improve voltage response based on the type of power generation from pyroelectric devices.

16. The system of claim 1, wherein said system is further configured as an S-NVBC type A capacitive module.

17. The system of claim 1, wherein said system is further configured as an S-NVBC type B resistive module.

18. The system of claim 1, wherein said system is further configured as an S-NVBC type C frequency module.
